(19) United States
(12) Patent Application Publication
(10) Pub. No.: US 2015/0279871 A1
(43) Pub. Date: Oct. 1, 2015

(54) SEMICONDUCTOR DEVICE, DISPLAY UNIT, AND ELECTRONIC APPARATUS

(71) Applicant: SONY CORPORATION, Tokyo (JP)

(72) Inventors: Narihiro Morosawa, Kanagawa (JP); Ayumu Sato, Tokyo (JP)

(73) Assignee: SONY CORPORATION, TOKYO (JP)

(21) Appl. No.: 14/438,937

(22) PCT Filed: Oct. 10, 2013
(86) PCT No.: PCT/JP2013/006044

§ 371 Date: Apr. 28, 2015

(30) Foreign Application Priority Data
Nov. 5, 2012 (JP) 2012-243319

(51) Int. Cl. H01L 27/12; H01L 29/786; H01L 49/02

(52) U.S. Cl. CPC H01L 27/1255; H01L 27/1225; H01L 28/40; H01L 29/78606

(57) ABSTRACT

Provided is a semiconductor device that includes a capacitor. The capacitor includes a hydrogen-containing film that is in contact with an oxide semiconductor film.

### CROSS REFERENCE TO RELATED APPLICATIONS

This application claims the benefit of Japanese Priority Patent Application JP2012-243319 filed Nov. 5, 2012, the entire contents of which are incorporated herein by reference.

### TECHNICAL FIELD

The present technology relates to a semiconductor device using an oxide semiconductor, and to a display unit and an electronic apparatus that include the semiconductor device.

### BACKGROUND ART

In an active-drive-type liquid crystal display unit and an organic EL (electroluminescence) display unit, a thin film transistor (TFT) is used as a drive element, and an electric charge corresponding to a signal voltage to write an image is held by a holding capacitor. However, in the case where a parasitic capacity generated in a cross region between a gate electrode and a source-drain electrode of a TFT is increased, in some cases, a signal voltage may be changed, leading to degradation of image quality.

In particular, in the organic EL display unit, in the case where a parasitic capacity is large, it is necessary to increase a holding capacity as well, and therefore, a rate occupied by wirings and the like is increased according to layout of pixels. As a result, probability of short-circuit between the wirings and/or the like is increased, and manufacturing yield is lowered.

Therefore, in a TFT in which an oxide semiconductor such as oxide zinc (ZnO) and indium gallium zinc oxide (IGZO) is used for a channel, a method of decreasing a parasitic capacity in a cross region between a gate electrode and a source-drain electrode has been proposed (for example, see PTLs 1 to 3 and NPLs 1 and 2).

In PTLs 1 to 3 and NPL 1, described is a top-gate-type TFT formed by a method in which after a gate insulating film and a gate electrode are provided on a channel region of an oxide semiconductor film in the same position in planar view, resistance of a region exposed from the gate electrode and the gate insulating film of the oxide semiconductor film is decreased to form a source-drain region, which is a so-called self-aligning method. In NPL 2, a bottom-gate-type TFT having a self-aligning structure is disclosed. In such a TFT, a source-drain region is formed in an oxide semiconductor film by rear surface exposure with the use of a gate electrode as a mask.

### CITATION LIST

### Patent Literature

PTL 1: JP 2007-220817A
PTL 2: JP 2011-228622A
PTL 3: JP 2012-15436A

### Non Patent Literature

NPL 1: J. Park et al., “Self-aligned top-gate amorphous gallium indium zinc oxide thin film transistors,” Applied Physics Letters, American Institute of Physics, 2008, Volume 93, 053501
NPL 2: R. Hayashi et al., “Improved Amorphous In—Ga—Zn—O TFTs,” SID 08 DIGEST, 2008, 42.1, pp. 621-624

### SUMMARY

### Technical Problem

As described above, the holding capacitor is arranged on the substrate together with the transistor using the oxide semiconductor. It is desirable that the holding capacitor hold a desired capacity stably.

It is desirable to provide a semiconductor device, a display unit, and an electronic apparatus that are capable of holding a desired capacity stably.

### Solution to Problem

According to an embodiment (1) of the present disclosure, there is provided a semiconductor device including: a transistor; a capacitor; and an oxide semiconductor film shared by the transistor and the capacitor. The capacitor includes a hydrogen-containing film that is in contact with the oxide semiconductor film.

According to an embodiment (2) of the present disclosure, there is provided a semiconductor device including: a capacitor including a hydrogen-containing film that is in contact with an oxide semiconductor film.

According to an embodiment of the present disclosure, there is provided a display unit provided with a plurality of display elements and a semiconductor device configured to drive the plurality of display elements. The semiconductor device includes: a transistor; a capacitor; and an oxide semiconductor film shared by the transistor and the capacitor, wherein the capacitor includes a hydrogen-containing film that is in contact with the oxide semiconductor film. According to an alternative embodiment, the semiconductor device may include a capacitor including a hydrogen-containing film that is in contact with an oxide semiconductor film.

According to an embodiment of the present disclosure, there is provided an electronic apparatus with a display unit. The display unit is provided with a plurality of display elements and a semiconductor device configured to drive the plurality of display elements. The semiconductor device includes: a transistor; a capacitor; and an oxide semiconductor film shared by the transistor and the capacitor, wherein the capacitor includes a hydrogen-containing film that is in contact with the oxide semiconductor film. According to an alternative embodiment, the semiconductor device may include a capacitor including a hydrogen-containing film that is in contact with an oxide semiconductor film.

In the semiconductor devices according to the above respective embodiments (1) and (2), as well as the display unit and the electronic apparatus according to the above embodiments of the present technology, hydrogen is diffused from the hydrogen-containing film to the oxide semiconductor film, and resistance of the oxide semiconductor film as one electrode of the capacitor is lowered.

### Advantageous Effects of Invention

According to the semiconductor devices of the above respective embodiments (1) and (2), as well as the display unit and the electronic apparatus of the above embodiments of the present technology, the capacitor includes the hydrogen-containing film. Therefore, a desired capacity is stably held without relation to a magnitude of applied voltage. Therefore, for example, display quality of the display unit is allowed to be improved.

It is to be understood that both the foregoing general description and the following detailed description are exemplary, and are intended to provide further explanation of the technology as claimed.

### BRIEF DESCRIPTION OF DRAWINGS

FIG. 1 is a cross-sectional view illustrating a configuration of a display unit according to an embodiment of the present technology.

FIG. 2A is a cross-sectional view illustrating a configuration of a holding capacitor illustrated in FIG. 1.

FIG. 2B is a plan view illustrating configurations of a hydrogen-containing film and a capacitor electrode illustrated in FIG. 2A.

FIG. 3A is a cross-sectional view illustrating another example of the holding capacitor illustrated in FIG. 1.

FIG. 3B is a plan view illustrating configurations of a hydrogen-containing film and a capacitor electrode illustrated in FIG. 3A.

FIG. 4A is a cross-sectional view illustrating still another example of the holding capacitor illustrated in FIG. 1.

FIG. 4B is a plan view illustrating configurations of a hydrogen-containing film and a capacitor electrode illustrated in FIG. 4A.

FIG. 5 is a plan view for explaining a positional relationship between a transistor and the holding capacitor illustrated in FIG. 1.

FIG. 6 is a plan view illustrating another example of the positional relationship between the transistor and the holding capacitor illustrated in FIG. 5.

FIG. 7 is a diagram illustrating a whole configuration including a peripheral circuit of the display unit illustrated in FIG. 1.

FIG. 8 is a diagram illustrating a circuit configuration of a pixel illustrated in FIG. 7.

FIG. 9A is a cross-sectional view illustrating a method of manufacturing the display unit illustrated in FIG. 1 in order of steps.

FIG. 9B is a cross-sectional view illustrating a step following a step of FIG. 9A.

FIG. 9C is a cross-sectional view illustrating a step following the step of FIG. 9B.

FIG. 10A is a cross-sectional view illustrating a step following the step of FIG. 9C.

FIG. 10B is a cross-sectional view illustrating a step following the step of FIG. 10A.

FIG. 10C is a cross-sectional view illustrating a step following the step of FIG. 10B.

FIG. 11 is a cross-sectional view illustrating a main section of a display unit according to a comparative example.

FIG. 12 is a diagram illustrating a relation between capacities of holding ca-pacitors illustrated in FIG. 1 and FIG. 11 and applied voltages.

FIG. 13 is a cross-sectional view illustrating a structure of a display unit according to Modification 1.

FIG. 14 is a cross-sectional view illustrating a structure of a display unit according to Modification 2.

FIG. 15 is a plan view illustrating a schematic configuration of a module including any of the display units according to the foregoing embodiment and the like.

FIG. 16A is a perspective view illustrating an appearance of Application example 1 of any of the display units according to the foregoing embodiment and the like.

FIG. 16B is a perspective view illustrating another example of the appearance of Application example 1 illustrated in FIG. 16A.

FIG. 17 is a perspective view illustrating an appearance of Application example 2.

FIG. 18 is a perspective view illustrating an appearance of Application example 3.

FIG. 19A is a perspective view illustrating an appearance of Application example 4 viewed from the front side thereof.

FIG. 19B is a perspective view illustrating an appearance of Application example 4 viewed from the rear side thereof.

FIG. 20 is a perspective view illustrating an appearance of Application example 5.

FIG. 21 is a perspective view illustrating an appearance of Application example 6.

FIG. 22A is a view illustrating a closed state of Application example 7.

FIG. 22B is a view illustrating an open state of Application example 7.

### DESCRIPTION OF EMBODIMENT

An embodiment of the present technology will be described in detail below with reference to the drawings. The description will be given in the following order.

1. Embodiment (an example in which a holding capacitor has a hydrogen-containing film: an organic EL display unit)

2. Modification 1 (a liquid crystal display unit)

3. Modification 2 (electronic paper)

4. Application Examples

### Embodiment

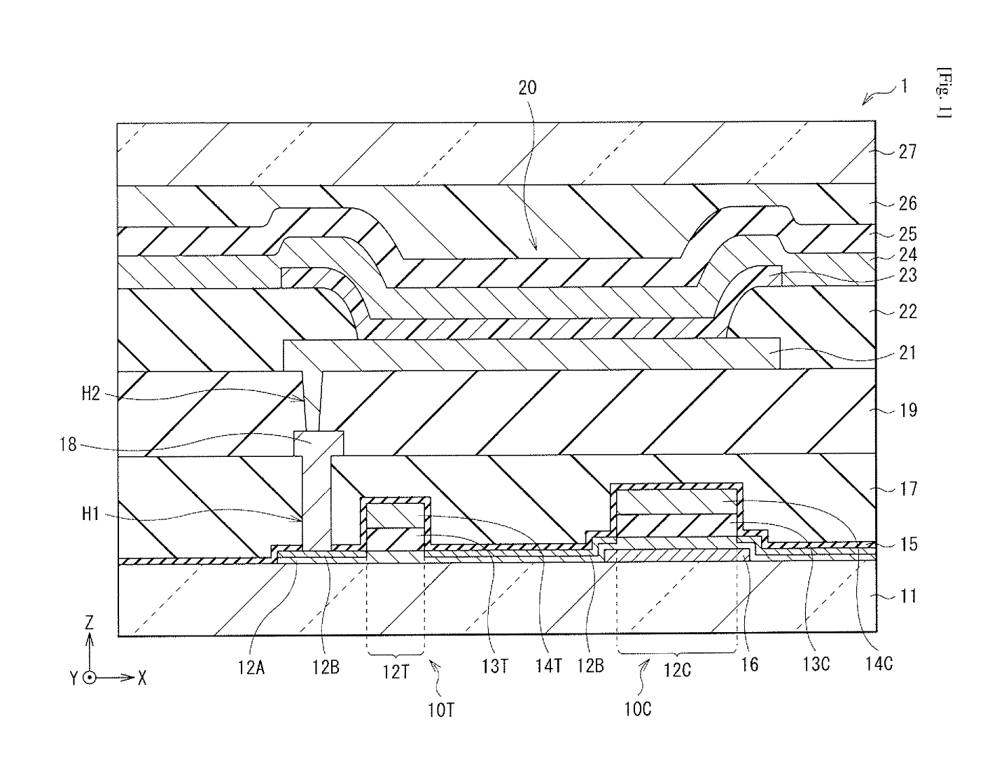

FIG. 1 illustrates a cross-sectional configuration of a display unit 1 (semiconductor device) according to an embodiment of the present technology. The display unit 1 is an active-matrix-type organic EL (electroluminescence) display unit, and has a plurality of transistors 10T having an oxide semiconductor film 12 and a plurality of organic EL elements 20 driven by the plurality of transistors 10T. FIG. 1 illustrates a region (sub-pixel) corresponding to one of the transistors 10T and one of the organic EL elements 20.

The display unit 1 has a holding capacitor 10C sharing the oxide semiconductor film 12 with one of the transistors 10T. One of the organic EL elements 20 is provided on the transistor 10T and the holding capacitor 10C with a planarizing film 19 in between. The transistor 10T is a staggered-structured (top-gate-type) TFT having a substrate 11, the oxide semiconductor film 12, a gate insulating film 13T, and a gate electrode 14T in this order. The oxide semiconductor film 12 and the gate electrode 14T are covered with an interlayer insulating film 17. A source-drain electrode 18 of the transistor 10T is electrically connected to the oxide semiconductor film 12 through a connection hole H1 of the interlayer insulating film 17.

(Transistor 10T)

The substrate 11 may be made, for example, a plate-like member such as quartz, glass, silicon, and a resin (plastic) film. An inexpensive resin film may be used, since the oxide semiconductor film 12 is formed without heating the substrate 11 in an after-mentioned sputtering method. Examples of the resin material may include PET (polyethylene terephthalate) and PEN (polyethylene naphthalate). In addition thereto, according to a purpose, a metal substrate such as a stainless steel (SUS) may be used.

The oxide semiconductor film 12 is provided in a selective region on the substrate 11, and has a function as an active layer of the transistor 10T. The oxide semiconductor film 12 may contain as a main component, for example, an oxide of one or more elements of indium (In), gallium (Ga), zinc (Zn), and tin (Sn). Specific examples thereof may include indium tin zinc oxide (ITZO) and indium gallium zinc oxide (IGZO: InGaZnO) as amorphous oxides. Further, specific examples thereof may include zinc oxide (ZnO), indium zinc oxide (IZO (registered trademark)), indium gallium oxide (IGO), indium tin oxide (ITO), and indium oxide (InO) as crystalline oxides. The thickness (thickness in a lamination direction (Z direction), and simply referred to as “thickness” below) of the oxide semiconductor film 12 may be, for example, about 50 nm.

The oxide semiconductor film 12 has a channel region 12T opposed to the gate electrode 14T as an upper layer, and has a pair of low resistance regions 12B (source-drain regions) that is adjacent to the channel region 12T and has electric re-sistivity lower than that of the channel region 12T. The low resistance regions 12B are provided in part of a thickness direction from a front surface (top surface) of the oxide semiconductor film 12, and may be formed by, for example, reaction of a metal such as aluminum (Al) with an oxide semiconductor material to spread the metal (dopant). The source-drain electrode 18 is electrically connected to the low resistance regions 12B. A self-aligning structure of the transistor 10T is achieved by the low resistance regions 12B. Further, the low resistance regions 12B also have a role to stabilize characteristics of the transistor 10T. Out of the oxide semiconductor film 12, a section configuring the transistor 10T is in contact with the substrate 11.

The gate electrode 14T is provided above the channel region 12T with the gate insulating film 13T in between. The gate electrode 14T has the same shape as that of the gate insulating film 13T in planar view. For example, the gate insulating film 13T may have a thickness of about 300 nm, and may be made of a single layer film configured of one of a silicon oxide film (SiO), a silicon nitride film (SiN), a silicon nitride oxide film (SiON), an aluminum oxide film (AlO), and the like, or may be made of a laminated film configured of two or more thereof. For the gate insulating film 13T, a material that is less likely to reduce the oxide semiconductor film 12 such as the silicon oxide film and the aluminum oxide film may be preferably used.

The gate electrode 14T controls carrier density in the oxide semiconductor film 12 (the channel region 12T) by a gate voltage (Vg) applied to the transistor 10T, and has a function as a wiring to supply an electric potential. The gate electrode 14T may be made of a simple substance configured of, for example, one of molybdenum (Mo), titanium (Ti), aluminum, silver (Ag), neodymium (Nd), and copper or an alloy thereof. The gate electrode 14T may have a laminated structure using a plurality of simple substances or a plurality of alloys. The gate electrode 14T may be configured of a laminated structure in which, for example, titanium, aluminum, and molybdenum are layered in this order from the oxide semiconductor film 14 side. The gate electrode 14T may be preferably made of a metal with low resistance such as aluminum and copper. The gate electrode 14T may be configured of a laminated structure in which a layer (barrier layer) made of, for example, titanium or molybdenum is layered on a layer (low resistance layer) made of a metal with low resistance. For the gate electrode 14T, an alloy containing a metal with low resistance such as an alloy of aluminum and neodymium (Al—Nd) may be used. The gate electrode 14T may be configured of a transparent conductive film such as ITO. The thickness of the gate electrode 14T may be, for example, from 10 nm to 500 nm both inclusive.

A high resistance film 15 is provided between the gate electrode 14T and the interlayer insulating film 17 and between the oxide semiconductor film 12 (the low resistance region 12B) and the interlayer insulating film 17. The high resistance film 15 covers end faces of the gate electrode 14T, end faces of the gate insulating film 13T, and an end face of the oxide semiconductor film 12, and also covers the holding capacitor 10C. The high resistance film 15 is obtained as a residual oxide film of a metal film (an after-mentioned metal film 15A in FIG. 10B) which serves as a supply source of a metal dispersed in the low resistance region 12B of the oxide semiconductor film 12 in an after-mentioned manufacturing step. Alternatively, the high resistance film 15 may be formed by further providing an insulating film with high barrier properties such as an aluminum oxide film on the residual oxide film. The high resistance film 15 may have a thickness of, for example, 20 nm or less, and may be made of titanium oxide, aluminum oxide, indium oxide, tin oxide, or the like. The high resistance film 15 may have a laminated structure in which a plurality of oxide films are layered. In the case where the insulating film with high barrier properties is layered on the high resistance film 15, the total thickness thereof may be, for example, about 50 nm. In addition to the foregoing roles in the process, the high resistance film 15 also has a function to reduce influence of oxygen and moisture that change electric characteristics of the oxide semiconductor film 12 in the transistor 10T, that is, a barrier function. Therefore, by providing the high resistance film 15, electric characteristics of the transistor 10T and the holding capacitor 10C are allowed to be stabilized, and effect of the interlayer insulating film 17 is allowed to be further improved.

The interlayer insulating film 17 is provided on the high resistance film 15. As the high resistance film 15 does, the interlayer insulating film 17 extends to outside of the oxide semiconductor film 12, and covers the gate electrode 14T and the oxide semiconductor film 12. The interlayer insulating film 17 may be made of, for example, an organic material such as an acryl resin, polyimide, and siloxane, or an inorganic material such as a silicon oxide film, a silicon nitride film, a silicon oxynitride film, and aluminum oxide. The interlayer insulating film 17 may be configured of a laminated structure in which the foregoing organic material and the foregoing inorganic material are layered. The thickness of the interlayer insulating film 17 containing the organic material is allowed to be easily increased to about 2 mi-crometers, for example. Such a thickened interlayer insulating film 17 is allowed to sufficiently cover steps such as a step between the gate insulating film 13T and the gate electrode 14T to secure insulation properties. Further, the interlayer insulating film 17 containing the organic material is allowed to decrease a wiring capacity formed by a metal wiring to achieve a large-scaled display unit 1 with a high frame rate. Therefore, in the transistor 10T having a self-aligning structure, the interlayer insulating film 17 containing an organic insulating material may be preferably used.

The source-drain electrode 18 is provided on the interlayer insulating film 17 in a state of a certain pattern, and is connected to the low resistance region 12B of the oxide semiconductor film 12 through the connection hole H1 penetrating the interlayer insulating film 17 and the high resistance film 15. The source-drain electrode 18 may be desirably provided in a location other than a location directly above the gate electrode 14T. One reason for this is that, in this case, a parasitic capacity is prevented from being formed in a cross region between the gate electrode 14T and the source-drain electrode 18. The thickness of the source-drain electrode 18 may be, for example, about 500 nm, and may be made of a material similar to the metals and the transparent electric conductive film that are listed above for the gate electrode 14T. The source-drain electrode 18 may be preferably made of a low resistance metal material such as aluminum and copper as well, and may be more preferably configured of a laminated film in which a low resistance layer and a barrier layer are laminated. One reason for this is that, in the case where the source-drain electrode 18 is configured of such a laminated film, drive with little wiring delay is achievable. An alloy of aluminum and neodymium may be provided on the uppermost layer of the source-drain electrode 18. Thereby, for example, the source-drain electrode 18 is allowed to have a function of a first electrode (an after-mentioned first electrode 21) of the organic EL element 20 as well.

(Holding Capacitor 10C)

The holding capacitor 10C is provided on the substrate 11 together with the transistor 10T, and may be, for example, a capacitor that holds electric charge in an after-mentioned pixel circuit 50A. The holding capacitor 10C has a capacitor insulating film 13C between a capacitor electrode 14C and the oxide semiconductor film 12. In the oxide semiconductor film 12, a section (an electrode-opposed region 12C) opposed to the capacitor electrode 14C functions as one electrode paired with the capacitor electrode 14C, and configures the holding capacitor 10C.

The holding capacitor 10C has a hydrogen-containing film 16, the oxide semiconductor film 12 (the electrode-opposed region 12C) shared with the transistor 10T, the capacitor insulating film 13C, and the capacitor electrode 14C in this order from the substrate 11 side. On the holding capacitor 10C, the high resistance film 15 and the interlayer insulating film 17 are provided in this order. Although details will be described later, in this embodiment, by proving the hydrogen-containing film 16 in the holding capacitor 10C as described above, a desired capacity is allowed to be held re-gardless of a magnitude of applied voltage. That is, voltage dependence of the holding capacitor 10C is allowed to be reduced.

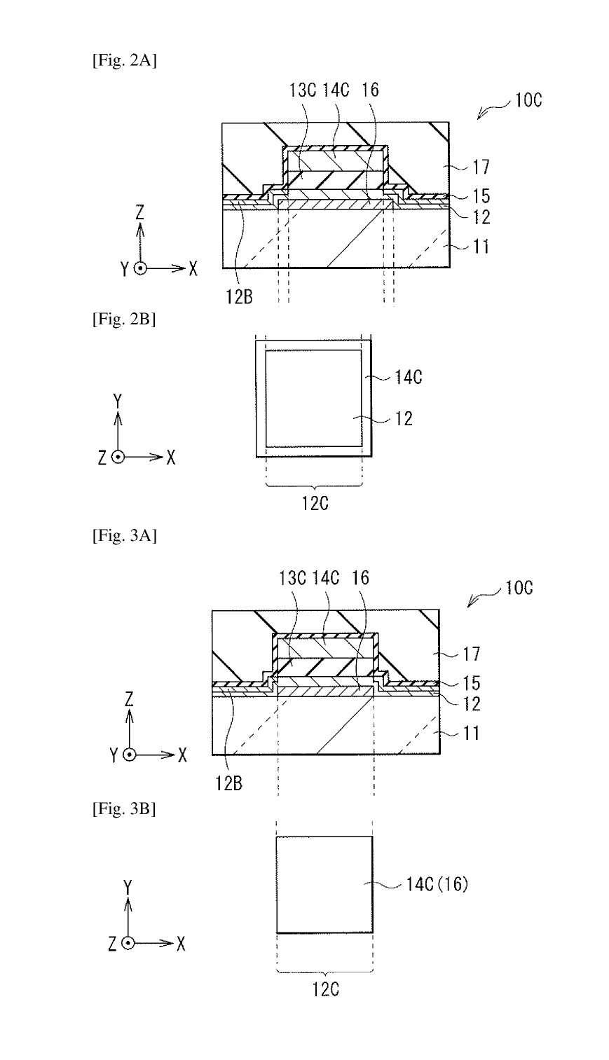

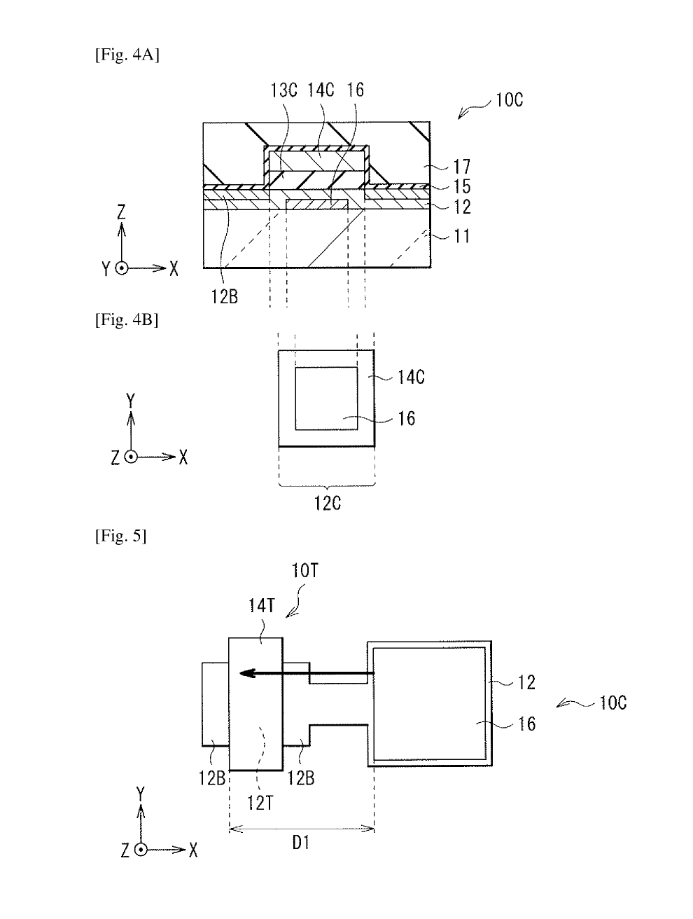

The hydrogen-containing film 16 may contain, for example, hydrogen (H₂) at a rate of about 10%, and the top surface thereof is in contact with the oxide semiconductor film 12. Thereby, hydrogen is diffused from the hydrogen-containing film 16 to the oxide semiconductor film 12, and resistance of the electrode-opposed region 12C is lowered. For the hydrogen-containing film 16, for example, a film containing silicon, more specifically, a silicon nitride film, a silicon oxide film, a silicon oxynitride film, or an amorphous silicon film may be used. End faces of the hydrogen-containing film 16 are located outside the end faces of the capacitor electrode 14C. The hydrogen-containing film 16 may preferably have a portion extending outside from the capacitor electrode 14C in planar view, and may more preferably extend outside from the whole circumference of the capacitor electrode 14C (FIG. 2A and FIG. 2B). Thereby, resistance of the electrode-opposed region 12C of the oxide semiconductor film 12 is securely decreased. As long as hydrogen is allowed to be diffused to the electrode-opposed region 12C, the end faces of the hydrogen-containing film 16 may be located in the same position as that of the end faces of the capacitor electrode 14 (FIG. 3A and FIG. 3B), or may be located inside the end faces of the capacitor electrode 14 (FIG. 4A and FIG. 4B). The thickness of the hydrogen-containing film 16 may be, for example, 200 nm.

The electrode-opposed region 12C of the oxide semiconductor film 12 does not have the low resistance region 12B as the channel region 12T, and electric resistance thereof in a thickness direction is constant. In other words, out of the oxide semiconductor film 12, the low resistance region 12B is provided in portions other than the channel region 12T and the electrode-opposed region 12C. The electrode-opposed region 12C of the oxide semiconductor film 12 may contain hydrogen diffused from the hydrogen-containing film 16 at a rate of, for example, about 1%.

In the case where the capacitor insulating film 13C is made of an inorganic insulating material, the holding capacitor 10C with a high capacity is obtainable. The capacitor insulating film 13C may be formed, for example, by the same step as that of the gate insulating film 13T, may be made of the same material as that of the gate insulating film 13T, and may have the same film thickness as that of the gate insulating film 13T. Further, the capacitor electrode 14C may be formed, for example, by the same step as that of the gate electrode 14T, may be made of the same material as that of the gate electrode 14T, and may have the same film thickness as that of the gate electrode 14T. The capacitor electrode 14C has the same shape as that of the capacitor insulating film 13C in planer view. The capacitor insulating film 13C and the gate insulating film 13T may be formed in different steps, may be made of different materials, and may have different film thicknesses. The capacitor electrode 14C and the gate electrode 14T may be formed in different steps, may be made of different materials, and may have different film thicknesses.

As illustrated in FIG. 5, the holding capacitor 10C may be preferably arranged along a channel length direction (X direction) of the transistor 10T with respect to the transistor 10T. One reason for this will be described below. In the case where hydrogen of the hydrogen-containing film 16 is diffused to the transistor 10T (the channel region 12T of the oxide semiconductor film 12), carrier density of the channel region 12T is increased, and threshold voltage Vₜₕ of the transistor 10T may be shifted in minus direction. Therefore, it is desirable that hydrogen from the hydrogen-containing film 16 be diffused only to the electrode-opposed region 12C, and do not reach the channel region 12T.

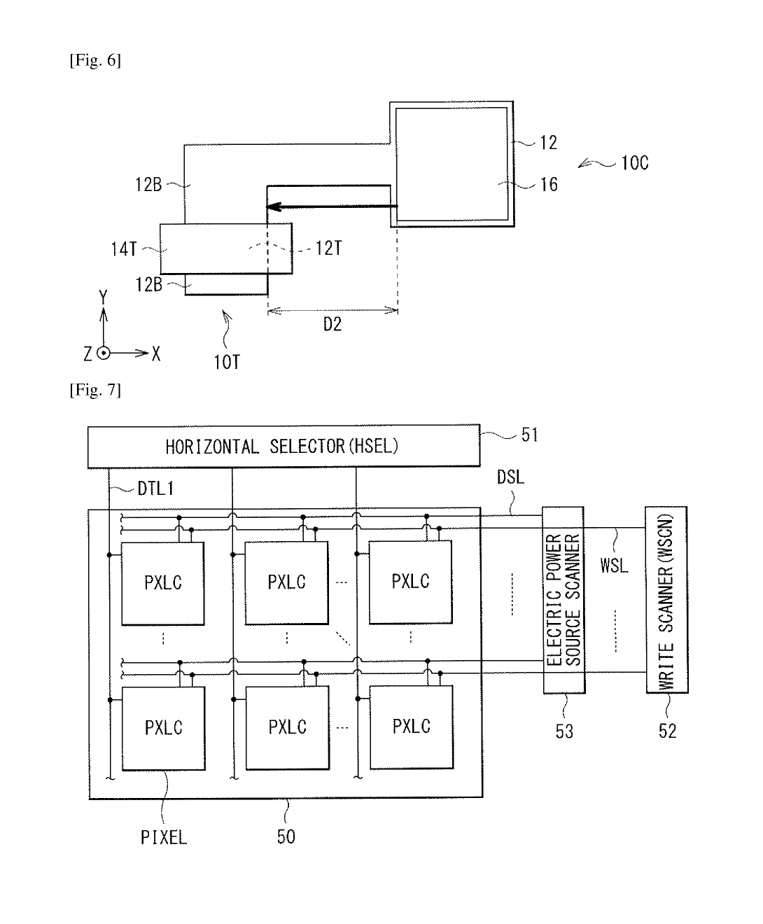

FIG. 6 illustrates a planar configuration in which the holding capacitor 10C is arranged in a channel width direction (Y direction) of the transistor 10T, that is, in a direction orthogonal to the channel length direction with respect to the transistor 10T. At this time, in the case where hydrogen is moved distance D2 from the hydrogen-containing film 16 to one end (the side close to the hydrogen-containing film 16) of the channel region 12T, the hydrogen is diffused between the pair of low resistance regions 12B (between the source-drain regions) of the oxide semiconductor film 12 to lower the resistance, which largely affects transistor characteristics. In contrast, in FIG. 5, even when hydrogen is moved from the hydrogen-containing film 16 to one end of the channel region 12T, the transistor characteristics hardly change. In other words, the transistor characteristics are allowed to be held until when hydrogen is moved distance D1 from the hydrogen-containing film 16 to the other end (the side far from the hydrogen-containing film 16) of the channel region 12T. Therefore, by arranging the transistor 10T and the holding capacitor 10C as illustrated in FIG. 5, the drive section (the transistor 10T and the holding capacitor 10C) of the display unit 1 is allowed to be miniaturized, and the transistor characteristics are allowed to be held.

The organic EL element 20 is provided on a planarizing film 19 (FIG. 1). The organic EL element 20 has the first electrode 21, a pixel separation film 22, an organic layer 23, and a second electrode 24 in this order from the planarizing film 19 side, and is sealed by a protective film 25. A sealing substrate 27 is bonded to the protective film 25 with an adhesion layer 26 made of a thermoset resin or an ultraviolet curable resin in between. The display unit 1 may be a bottom-emission-type display unit in which light generated in the organic layer 23 is extracted from the substrate 11 side, or may be a top-emission-type display unit in which light generated in the organic layer 23 is extracted from the sealing substrate 27 side.

The planarizing film 19 is provided on the source-drain electrode 18 and the interlayer insulating film 17 in the entire display region (an after-mentioned display region 50 in FIG. 7) of the substrate 11, and has a connection hole H2. The connection hole H2 connects the source-drain electrode 18 of the transistor 10T to the first electrode 21 of the organic EL element 20. The planarizing film 19 may be made of, for example, polyimide or an acryl-based resin.

The first electrode 21 is so provided on the planarizing film 19 as to bury the connection hole H2. The first electrode 21 may function, for example, as an anode, and may be provided for each element. In the case where the display unit 1 is a bottom-emission-type display unit, the first electrode 21 may be configured of a transparent conductive film. Examples thereof may include a single-layer film made of, for example, one of indium tin oxide (ITO), indium zinc oxide (IZO), indium zinc oxide (InZnO), and the like, and a laminated film configured of two or more thereof. In the case where the display unit 1 is a top-emission-type display unit, the first electrode 21 may be made of a single-layer film made of a reflective metal such as a single metal including aluminum, magnesium (Mg), calcium (Ca), and sodium (Na), may be configured of a single-layer film made of an alloy containing one or more thereof, or may be configured of a multi-layer film in which a single metal or an alloy are layered.

The pixel separation film 22 secures insulation properties between the first electrode 21 and the second electrode 24, and separates respective light emission regions of respective elements into sections. The pixel separation film 22 has an opening opposed to each light emission region of each element. The pixel separation film 22 may be made of, for example, a photosensitive resin such as polyimide, an acryl resin, and a novolak-based resin.

The organic layer 23 is so provided as to cover the opening of the pixel separation film 22. The organic layer 23 includes an organic electric field light emission layer (an organic EL layer), and emits light by being applied with a drive current. The organic layer 23 may have, for example, a hole injection layer, a hole transport layer, the organic EL layer, and an electron transport layer in this order from the substrate 11 (the first electrode 21) side. Electron-hole recombination is generated in the organic EL layer, and thereby light is generated. A constituent material of the organic EL layer is not particularly limited, as long as the constituent material of the organic EL layer is a general low-molecular organic material or a general polymer organic material. For example, organic EL layers that emit red light, green light, and blue light may be provided in a color-coded fashion for the respective elements. Alternatively, an organic EL layer emitting white light (for example, a laminated layer in which red, green, and blue organic EL layers are layered) may be provided on the whole surface of the substrate 11. The hole injection layer increases hole injection efficiency, and prevents leakage. The hole transport layer increases efficiency of hole transport to the organic EL layer. Layers such as the hole injection layer, the hole transport layer, and the electron transport layer other than the organic EL layer may be provided as necessary.

The second electrode 24 may function, for example, as a cathode, and may be configured of a metal conductive film. In the case where the display unit 1 is a bottom-emission-type display unit, the second electrode 24 may be configured of a single-layer film made of a reflective metal such as a single metal including, for example, aluminum, magnesium (Mg), calcium (Ca), and sodium (Na), may be configured of a single-layer film made of an alloy containing one or more thereof, or may be configured of a multi-layer film in which single metals or alloys are layered. In the case where the display unit 1 is a top-emission-type display unit, a transparent conductive film made of a material such as ITO and IZO may be used for the second electrode 24. For example, the second electrode 24 may be provided commonly to the respective elements in a state of being insulated from the first electrode 21.

The protective film 25 may be made of an insulating material or a conductive material. Examples of the insulating material may include amorphous silicon (a-Si), amorphous silicon carbide (a-SiC), amorphous silicon nitride (a-Si₍₁₋ₓ₎Nₓ), and amorphous carbon (a-C).

The sealing substrate 27 is arranged to oppose to the substrate 11 with the transistor 10T, the holding capacitor 10C, and the organic EL element 20 in between. For the sealing substrate 27, a material similar to that of the foregoing substrate 11 may be used. In the case where the display unit 1 is a top-emission-type display unit, a transparent material may be used for the sealing substrate 27, and a color filter and a light shielding film may be provided on the sealing substrate 27 side. In the case where the display unit 1 is a bottom-emission-type display unit, the substrate 11 may be made of a transparent material, and for example, a color filter and a light shielding film may be provided on the substrate 11 side.

### (Configurations of Peripheral Circuit and Pixel Circuit)

As illustrated in FIG. 7, the display unit 1 has a plurality of pixels PXLC including the foregoing organic EL element 20. The pixels PXLC may be arranged, for example, in a matrix pattern in the display region 50 on the substrate 11. Around the display region 50, a horizontal selector (HSEL) 51 as a signal line drive circuit, a write scanner (WSCN) 52 as a scanning line drive circuit, and an electric power source scanner 53 as an electric power source line drive circuit are provided.

In the display region 50, a plurality of (integer n-number of) signal lines DTL1 to DTLn are arranged in a column direction, and a plurality of (integer m-number of) scanning lines WSL1 to WSLm are arranged in a row direction. One of the pixels PXLC (one of pixels corresponding to R, G, and B) is provided in each intersection of one of signal lines DTL and one of the scanning lines WSL. Each of the signal lines DTL is electrically connected to the horizontal selector 51, and an image signal is supplied from the horizontal selector 51 to each of the pixels PXLC through each of the signal lines DTL. Each of the scanning lines WSL is electrically connected to the write scanner 52, and a scanning signal (selective pulse) is supplied from the write scanner 52 to each of the pixels PXLC through each of the scanning lines WSL. Each of electric power lines DSL is connected to the electric power source scanner 53, and an electric power source signal (control pulse) is supplied from the electric power source scanner 53 to each of the pixels PXLC through each of the electric power source lines DSL.

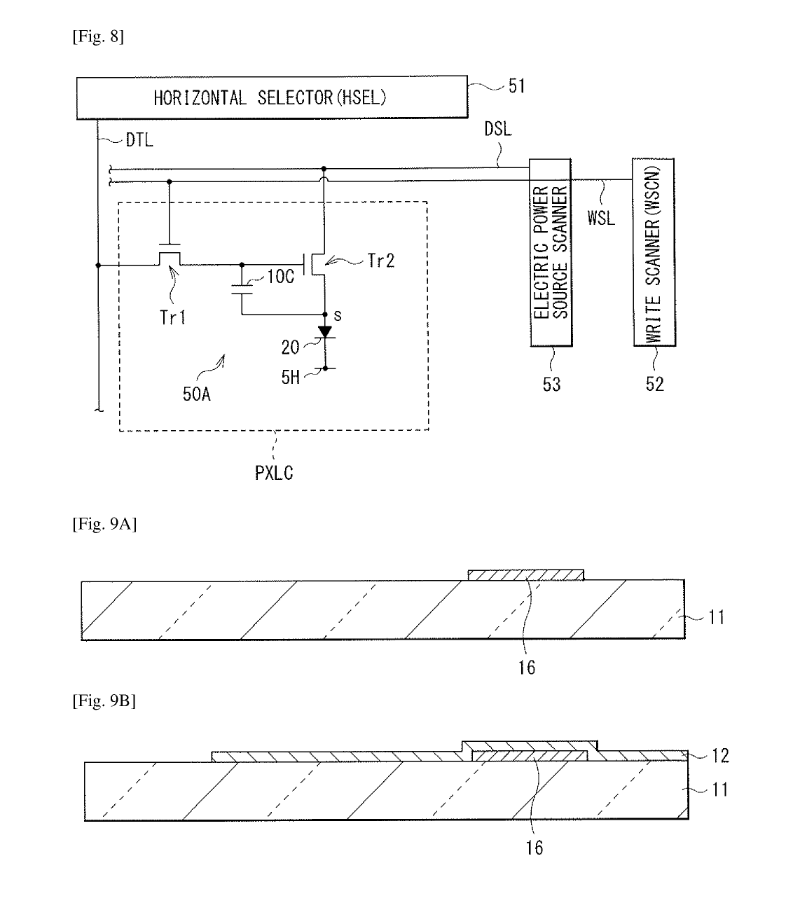

FIG. 8 illustrates a specific example of a circuit configuration in one of the pixels PXLC. Each of the pixels PXLC has a pixel circuit 50A including the organic EL element 20. The pixel circuit 50A is an active-type drive circuit having a sampling-use drive transistor Tr1, a drive-use transistor Tr2, the holding capacitor 10C, and the organic EL element 20. It is to be noted that one or more of the sampling-use drive transistor Tr1 and the drive-use transistor Tr2 correspond to the transistor 10T according to the foregoing embodiment and the like.

A gate of the sampling-use drive transistor Tr1 is connected to the corresponding scanning line WSL. One of a source and a drain of the sampling-use drive transistor Tr1 is connected to the corresponding signal line DTL, and the other thereof is connected to a gate of the drive-use transistor Tr2. A drain of the drive-use transistor Tr2 is connected to the corresponding electric power source line DSL, and a source thereof is connected to an anode of the organic EL element 20. Further, a cathode of the organic EL element 20 is connected to a grounding link 5H. It is to be noted that the grounding link 5H is commonly provided for all of the pixels PXLC. The holding capacitor 10C is arranged between the source and the gate of the drive-use transistor Tr2.

The sampling-use drive transistor Tr1 conducts electricity according to the scanning signal (selective pulse) supplied from the scanning line WSL, and thereby, performs sampling of a signal electric potential of an image signal supplied from the signal line DTL, and holds the sampled signal electric potential in the holding capacitor 10C. The drive-use transistor Tr2 is supplied with a current from the electric power source line DSL set to a predetermined first electric potential (not illustrated), and supplies a drive current to the organic EL element 20 according to the signal electric potential held in the holding capacitor 10C. The organic EL element 20 emits light with luminance according to the signal electric potential of the image signal by the drive current supplied from the drive-use transistor Tr2.

In the foregoing circuit configuration, the sampling-use transistor Tr1 conducts electricity according to the scanning signal (selective pulse) supplied from the scanning line WSL, and thereby, a signal electric potential of the image signal supplied from the signal line DTL is sampled, and the sampled signal electric potential is held in the holding capacitor 10C. Further, a current is supplied from the electric power source line DSL set to the foregoing first electric potential to the drive-use transistor Tr2, and a drive current is supplied to the organic EL element 20 (each of the organic EL elements 20 of red, green, and blue) according to the signal electric potential held in the holding capacitor 10C. Each of the organic EL elements 20 emits light with luminance according to the signal electric potential of the image signal by the supplied drive current. Thereby, an image is displayed based on the image signal in the display unit 1.

Such a display unit 1 may be manufactured, for example, as follows.

(Steps of Forming Transistor 10T and Holding Capacitor10C)

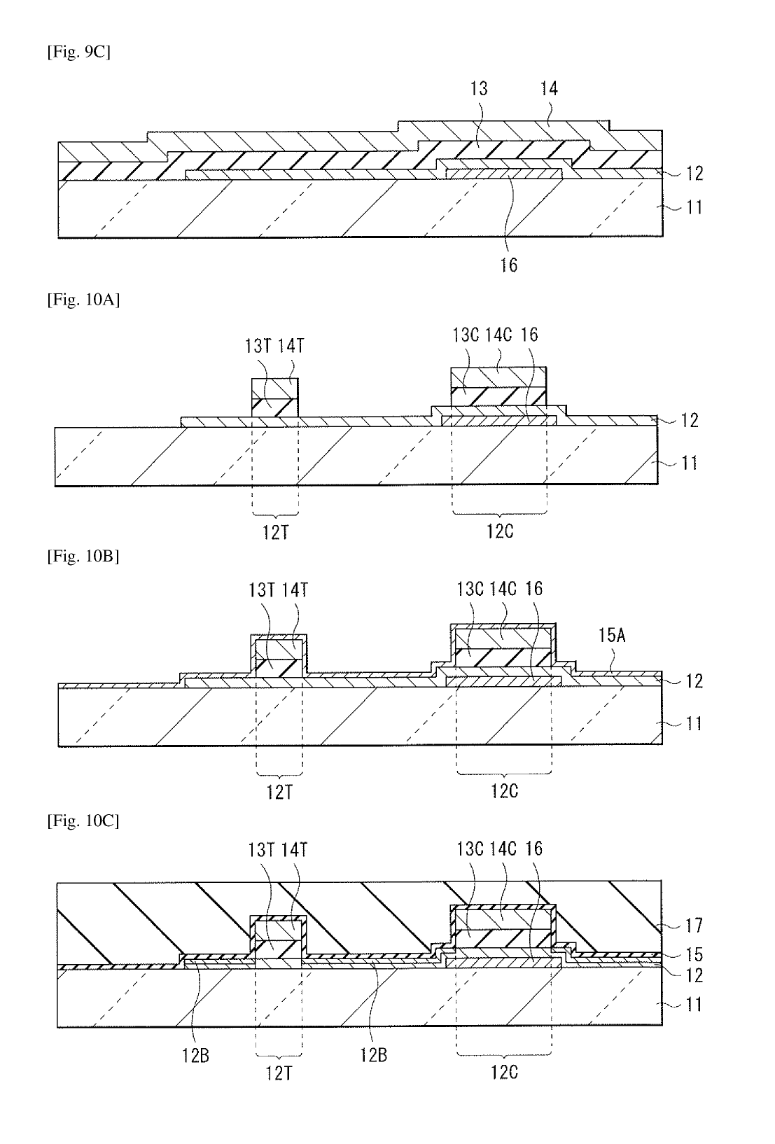

First, as illustrated in FIG. 9A, the hydrogen-containing film 16 is formed in a region including a region where the holding capacitor 10C is to be formed so that the hydrogen-containing film 16 is in contact with the substrate 11 made of a plate-like member. Specifically, first, a silicon nitride film being about 200 nm thick may be formed on the whole surface of the substrate 11 by, for example, a plasma CVD (Chemical Vapor Deposition) method. Thereafter, the resultant is patterned in a shape of an island by photolithography and etching. In order to increase hydrogen concentration, the hydrogen-containing film 16 may be preferably formed at comparatively low temperature such as temperature equal to or less than 200 deg C. The hydrogen-containing film 16 may be formed by a sputtering method while hydrogen is supplied.

Next, for example, a material film for an oxide semiconductor film (not illustrated) being 50 nm thick may be formed on the substrate 11 and the hydrogen-containing film 16. Thereafter, the resultant is patterned to form the oxide semiconductor film 12 (FIG. 9B). The material film for the oxide semiconductor film may be formed by, for example, a sputtering method. At this time, as a target, ceramic having the same composition as that of an oxide semiconductor to be formed as a film is used. Further, carrier density in the oxide semiconductor largely depends on oxygen partial pressure at the time of sputtering, and therefore, the oxygen partial pressure is controlled so that desired transistor characteristics are obtained. The patterning of the material film for the oxide semiconductor film may be performed by, for example, photolithography and etching. At this time, processing may be preferably made by wet etching with the use of a mixed solution of phosphoric acid, nitric acid, and acetic acid. Using the mixed solution of phosphoric acid, nitric acid, and acetic acid allows sufficient increase of selected ratio with respect to a base foundation, and allows comparatively easy processing. In the case where the oxide semiconductor film 12 is made of a crystalline material such as ZnO, IZO, and IGO, etching selectivity is allowed to be improved easily in an after-mentioned etching step of the gate insulating film 13T (or the capacitor insulating film 13C).

Subsequently, as illustrated in FIG. 9C, for example, the insulating film 13 configured of a silicon oxide film or an aluminum oxide film being 200 nm thick and the conductive film 14 made of a metal material such as molybdenum, titanium, and aluminum being 500 nm thick are formed in this order on the whole surface of the substrate 11. The insulating film 13 may be formed by, for example, a plasma CVD method. The insulating film 13 configured of a silicon oxide film may be formed by a reactive sputtering method besides the plasma CVD method. Further, in the case where the aluminum oxide film is used for the insulating film 13, an atomic layer film formation method may be used besides the foregoing reactive sputtering method and the foregoing CVD method. The conductive film 14 may be formed by, for example, a sputtering method.

After the conductive film 14 is formed, the conductive film 14 may be patterned by, for example, photolithography and etching to form the gate electrode 14T and the capacitor electrode 14C in a selective region (the channel region 12T and the electrode-opposed region 12C) on the oxide semiconductor film 12. Next, the insulating film 13 is etched with the use of the gate electrode 14T and the capacitor electrode 14C as a mask. Thereby, the gate insulating film 13T is patterned in the substantially same shape as that of the gate electrode 14T, and the capacitor insulating film 13C is patterned in the substantially same shape as that of the capacitor electrode 14C respectively in planar view (FIG. 10A). In the case where the oxide semiconductor film 12 is made of the foregoing crystalline material, by using a chemical solution such as hydrofluoric acid in the etching step, the insulating film 13 is allowed to be easily processed while significantly large etching selected ratio is maintained. The capacitor insulating film 13C and the capacitor electrode 14C of the holding capacitor 10C may be formed with the use of materials different from those of the insulating film 13 and the conductive film 14 after the gate electrode 14T and the gate insulating film 13T are formed.

Subsequently, as illustrated in FIG. 10B, the metal film 15A which may be made of, for example, titanium, aluminum, tin, indium, or the like having a thickness, for example, from 5 nm to 10 nm both inclusive may be formed on the whole surface of the substrate 11 by, for example, a sputtering method. The metal film 15A is made of a metal that reacts with oxygen at comparatively low temperature, and formed to be in contact with portions of the oxide semiconductor film 12 other than the portion where the gate electrode 14T and the capacitor electrode 14C are formed. An insulating film (not illustrated) with high barrier properties may be layered on the metal film 15A after the metal film 15A is formed. As the insulating film, for example, an aluminum oxide film being 50 nm thick may be formed by a sputtering method or an atomic layer formation method.

Next, the metal film 15A may be oxidized by performing heat treatment under oxygen atmosphere at, for example, about 200 deg C. Thereby, the high resistance film 15 configured of a metal oxide film is formed. At this time, in a region other than the channel region 12T and the electrode-opposed region 12C of the oxide semiconductor film 12, the low resistance region 12B (including the source-drain region) is formed in part on the high resistance film 15 side in the thickness direction. For the oxidation reaction of the metal film 15A, part of oxygen contained in the oxide semiconductor film 12 is utilized. Therefore, as the oxidation of the metal film 15A proceeds, in the oxide semiconductor film 12, oxygen concentration is decreased from the front surface (top surface) side of the oxide semiconductor film 12 in contact with the metal film 15A. On the other hand, from the metal film 15A, a metal such as aluminum is diffused in the oxide semiconductor film 12. The metal element functions as a dopant, and resistance of a region on the top surface side of the oxide semiconductor film 12 in contact with the metal film 15A is lowered. Thereby, the low resistance region 12B with electric resistance lower than those of the channel region 12T and the electrode-opposed region 12C is formed.

As the heat treatment of the metal film 15A, annealing may be preferably performed at about 200 deg C as described above. At this time, by performing the annealing in oxidizing gas atmosphere containing oxygen and the like, oxygen concentration of the low resistance region 12B is suppressed from being excessively lowered, and sufficient oxygen is allowed to be supplied to the oxide semiconductor film 12. Thereby, steps are allowed to be simplified by reducing an annealing step performed in a subsequent step.

Instead of the foregoing annealing step, the high resistance film 15 may be formed by, for example, setting temperature of the substrate 11 at the time of forming the metal film 15A on the substrate 11 to a relatively high value. For example, in the case where the metal film 15A is formed while temperature of the substrate 11 is kept at about 200 deg C in the step of FIG. 10B, resistance of a predetermined region of the oxide semiconductor film 12 is allowed to be decreased without performing heat treatment. In this case, carrier density of the oxide semiconductor film 12 is allowed to be decreased down to a level necessary as a transistor.

The metal film 15A may be preferably formed to have a thickness equal to or less than 10 nm as descried above. In the case where the thickness of the metal film 15A is equal to or less than 10 nm, the metal film 15A is allowed to be completely oxidized (the high resistance film 15 is allowed to be formed) by heat treatment. In the case where the metal film 15A is not completely oxidized, it is necessary to perform a step of removing the non-oxidized metal film 15A by etching. One reason for this is that, in the case where the metal film 15A that is not sufficiently oxidized is left on the gate electrode 14T, the capacitor electrode 14C, and/or the like, a leak current may be generated. In the case where the metal film 15A is completely oxidized, and the high resistance film 15 is formed, the foregoing removal step is not necessitated, and manufacturing steps are allowed to be simplified. That is, even if the removal step is not performed by etching, a leak current may be prevented from being generated. It is to be noted that, in the case where the metal film 15A is formed to have a thickness equal to or less than 10 nm, the thickness of the high resistance film 15 after heat treatment is equal to or less than about 20 nm.

As described above, an insulating film with high barrier properties such as an aluminum oxide film may be preferably formed on the metal film 15A, and the high resistance film 15 may be preferably formed by the oxidized metal film 15A and the insulating film. Accordingly, the high resistance film 15 has a sufficient protective function.

As a method of oxidizing the metal film 15A, besides the foregoing heat treatment, a method such as oxidation in moisture vapor atmosphere and plasma oxidation may be used. In particular, the plasma oxidation has the following advantage. After the high resistance film 15 is formed, the interlayer insulating film 17 is formed by a plasma CVD method (after-mentioned FIG. 10C). In this case, after plasma oxidation treatment is performed on the metal film 15A, the interlayer insulating film 17 is allowed to be formed subsequently (continuously). Therefore, such a method has an advantage that the number of steps does not have to be increased. For example, in the plasma oxidation, temperature of the substrate 11 may be desirably from about 200 deg C to about 400 deg C both inclusive, and plasma may be desirably generated in gas atmosphere containing oxygen such as mixed gas of oxygen and dinitrogen oxide to perform processing. By the foregoing step, the high resistance film 15 having a function to decrease influence of oxygen and moisture is allowed to be formed.

Further, as a method of decreasing resistance of the predetermined region of the oxide semiconductor film 12, besides the foregoing method by the reaction between the metal film 15A and the oxide semiconductor film 12, a method of decreasing resistance of the predetermined region of the oxide semiconductor film 12 by plasma treatment, a method of forming a silicon nitride film by a plasma CVD method to decrease resistance of the predetermined region of the oxide semiconductor film 12 by diffusion of hydrogen from the silicon nitride film, or the like may be used.

After the high resistance film 15 is formed, as illustrated in FIG. 10C, the interlayer insulating film 17 is formed on the whole surface of the high resistance film 15. In the case where the interlayer insulating film 17 contains an inorganic insulating material, for example, a plasma CVD method, a sputtering method, or an atomic layer film formation method may be used. In the case where the interlayer insulating film 17 contains an organic insulating material, for example, a coating method such as a spin coat method and a slit coat method may be used. By the coating method, the interlayer insulating film 17 having an increased film thickness is allowed to be formed easily. Subsequently, an exposure step and an image development step are performed to form the connection hole H1 in a predetermined location of the interlayer insulating film 17. In the case where a photosensitive resin is used for the interlayer insulating film 17, exposure and image development may be performed by the photosensitive resin to form the connection hole H1 in the predetermined location.

Subsequently, a conductive film (not illustrated) which eventually serves as the source-drain electrode 18 made of the foregoing material or the like may be formed on the interlayer insulating film 17 by, for example, a sputtering method, and the connection hole H1 is buried by the conductive film. Thereafter, the conductive film may be patterned in a predetermined shape by, for example, photolithography and etching. Thereby, the source-drain electrode 18 is formed on the interlayer insulating film 17, and the source-drain electrode 18 is electrically connected to the low resistance region 12B of the oxide semiconductor film 12 through the connection hole H1.

### (Step of Forming Planarizing Film 19)

After the transistor 10T and the holding capacitor 10C are formed as described above, the planarizing film 19 made of the foregoing material may be so formed as to cover the interlayer insulating film 17 and the source-drain electrode 18 by, for example, a spin coat method or a slit coat method, and the connection hole H2 is formed in part of a region opposed to the source-drain electrode 18.

### (Step of Forming Organic EL Element 20)

Subsequently, the organic EL element 20 is formed on the planarizing film 19. Specifically, the first electrode 21 made of the foregoing material may be so formed as to bury the connection hole H2 on the planarizing film 19 by, for example, a sputtering method. Thereafter, the resultant is patterned by photolithography and etching. Thereafter, the pixel separation film 22 having an opening is formed on the first electrode 21, and subsequently, the organic layer 23 may be formed by, for example, a vacuum evaporation method. Subsequently, the second electrode 24 made of the foregoing material may be formed on the organic layer 23 by, for example, a sputtering method. Next, the protective film 25 may be formed on the second electrode 24 by, for example, a CVD method. Thereafter, the sealing substrate 27 is bonded to the protective film 25 with use of the adhesion layer 26. By the foregoing steps, the display unit 1 illustrated in FIG. 1 is completed.

In the display unit 1, for example, in the case where a drive current according to an image signal of each color is applied to each of the pixels PXLC corresponding to one of R, G, and B, electrons and holes are injected into the organic layer 23 through the first electrode 21 and the second electrode 24. Recombination of the electrons and the holes occurs in the organic EL layer contained in the organic layer 23, and light is emitted. As described above, in the display unit 1, for example, full-color images of R, G, and B are displayed. Further, by applying an electric potential corresponding to an image signal to one end of the holding capacitor 10C at the time of operation of the image display, an electric charge corresponding to the image signal is stored in the holding capacitor 10C.

In this embodiment, since the hydrogen-containing film 16 is provided in the holding capacitor 10C, the holding capacitor 10C is allowed to hold a desired capacity stably without relation to an applied voltage. Details thereof will be described below.

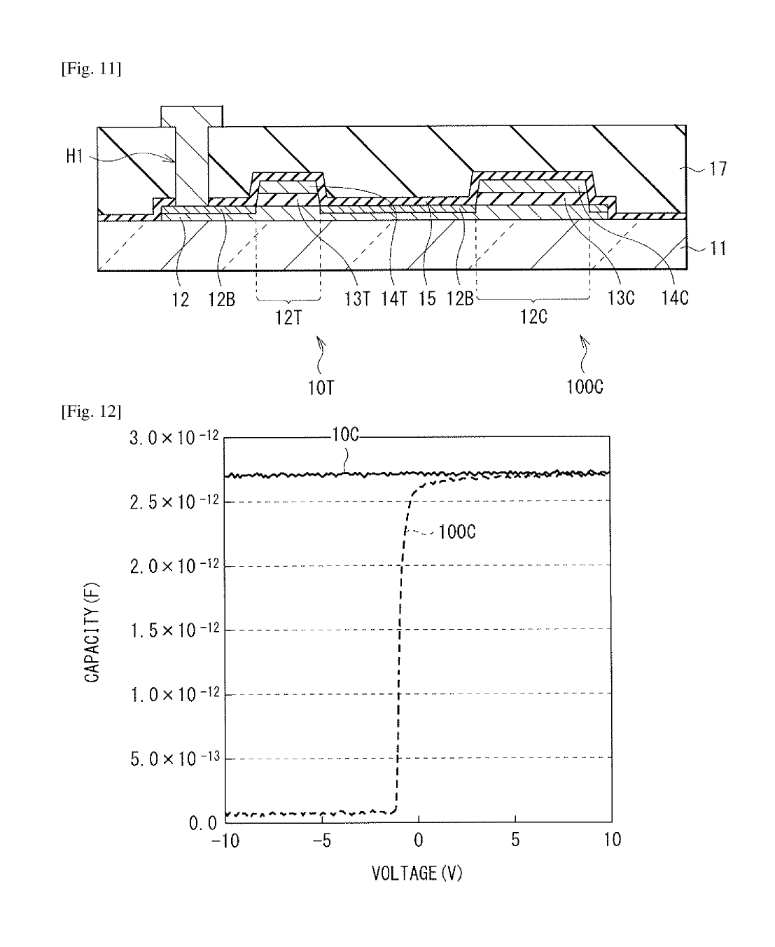

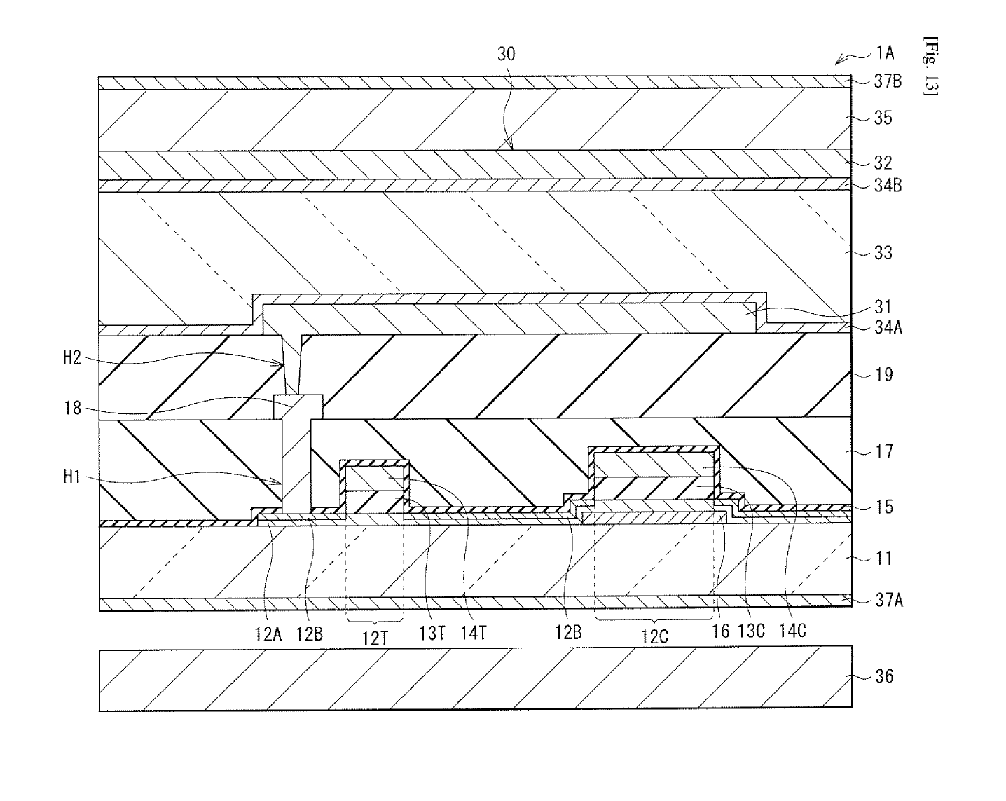

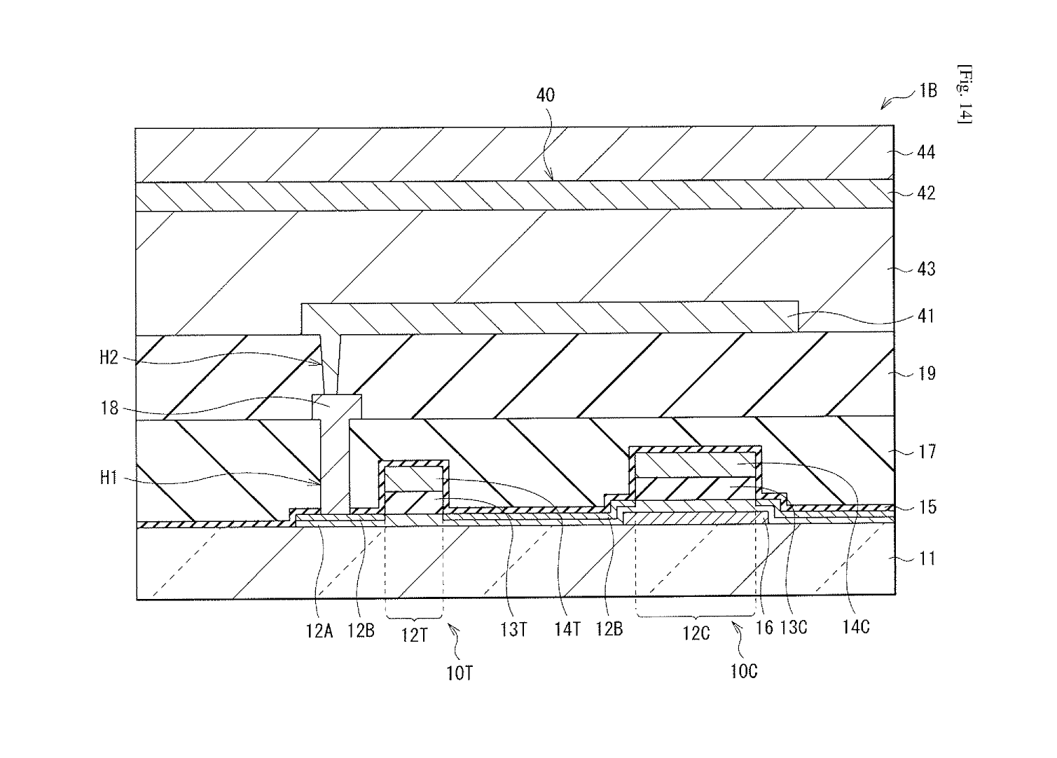

FIG. 11 illustrates cross-sectional configurations of the transistor 10T and a holding capacitor 100C of a display unit (display unit 100) according to a comparative example. The holding capacitor 100C is not provided with a hydrogen-containing film. As in the transistor 10T, in the holding capacitor 100C, the oxide semiconductor film 12 is in contact with the substrate 11. In the holding capacitor 100C in which the capacitor insulating film 13C is provided between the oxide semiconductor film 12 (the electrode-opposed region 12C) and the capacitor electrode 14C, as illustrated in FIG. 12, the capacity is largely varied according to a magnitude of applied voltage. That is, the holding capacitor 100C has voltage dependence.

In contrast, the holding capacitor 10C of the display unit 1 is provided with the hydrogen-containing film 16 in contact with the oxide semiconductor film 12. Therefore, when hydrogen is diffused from the hydrogen-containing film 16 to the oxide semiconductor film 12, the hydrogen functions as a donor in the electrode-opposed region 12C, and carrier density is increased. Therefore, resistance of the electrode-opposed region 12C of the oxide semiconductor film 12 is decreased, and a desired capacity is stably held in the holding capacitor 10C without relation to a magnitude of applied voltage (FIG. 12). In FIG. 12, a silicon nitride film being 200 nm thick formed by a plasma CVD method is used as the hydrogen-containing film 16.

As described above, in this embodiment, the holding capacitor 10C has the hydrogen-containing film 16. Therefore, voltage dependence is decreased, and a desired capacity is allowed to be stably held in the holding capacitor 10C. That is, since a sufficient capacity is held in the holding capacitor 10C without relation to an operating voltage, display quality is improved, for example.

Further, since the low resistance region 12B is provided in the oxide semiconductor film 12 to have a so-called self-aligning structure, parasitic capacity is allowed to be decreased. Further, since the oxide semiconductor film 12 shared with the transistor 10T is used for the holding capacitor 10C, the manufacturing steps are allowed to be simplified. Since the hydrogen-containing film 16 is allowed to be easily formed, the display unit 1 with high display quality is allowed to be formed by a simple manufacturing method.

A description will be given below of modifications of this embodiment. In the following description, for the same components as those of the foregoing embodiment, the same referential symbols are affixed thereto, and the description thereof will be omitted as appropriate.

### Modification 1

FIG. 13 illustrates a cross sectional configuration of a display unit (a display unit 1A) according to Modification 1 of the foregoing embodiment. The display unit 1A has a liquid crystal display element 30 instead of the organic EL element 20 of the display unit 1. Except for the foregoing point, the display unit 1A has a configuration similar to that of the display unit 1 according to the foregoing embodiment, and the operation and the effect thereof are similar to those of the display unit 1 according to the foregoing embodiment.

The display unit 1A has the transistor 10T and the holding capacitor 10C similar to those of the display unit 1. Above the transistor 10T and the holding capacitor 10C, the liquid crystal display element 30 is provided with the planarizing film 19 in between.

In the liquid crystal display element 30, a liquid crystal layer 33 is sealed between a pixel electrode 31 and a counter electrode 32. Alignment films 34A and 34B are provided on respective surfaces on the liquid crystal layer 33 side of the pixel electrode 31 and the counter electrode 32. The pixel electrode 31 is arranged for each pixel, and may be, for example, electrically connected to the source-drain electrode 18 of the transistor 10T. The counter electrode 32 is provided on an opposed substrate 35 as an electrode common to a plurality of pixels, and may be held at, for example, common electric potential. The liquid crystal layer 33 may be configured of liquid crystal driven by VA (Vertical Alignment) mode, TN (Twisted Nematic) mode, IPS (In Plane Switching) mode, or the like.

A backlight 36 is provided below the substrate 11. Polarizing plates 37A and 37B are bonded to the backlight 36 side of the substrate 11 and to the opposed substrate 35.

The backlight 36 is a light source to radiate light toward the liquid crystal layer 33, and may include, for example, a plurality of LEDs (Light Emitting Diodes), a plurality of CCFL (Cold Cathode Fluorescent Lamps), and the like. A lighting state and an ex-tinction state of the backlight 36 are controlled by an unillustrated backlight drive section.

The polarizing plates 37A and 37B (light polarizers or light analyzers) may be arranged, for example, in crossed Nicole positional relationship. Thereby, for example, illuminated light from the backlight 36 is blocked in a state that a voltage is not applied (off state), and is transmitted in a state that a voltage is applied (on state).

In the display unit 1A, as in the display unit 1 of the foregoing embodiment, resistance of the opposed region 12C of the oxide semiconductor film 12 is decreased by the hydrogen-containing film 16. Therefore, in this modification as well, voltage dependence of the holding capacitor 10C is allowed to be suppressed, and a desired capacity is allowed to be held stably.

### Modification 2

FIG. 14 illustrates a cross sectional configuration of a display unit (a display unit 1B) according to Modification 2 of the foregoing embodiment. The display unit 1B is a so-called electronic paper, and has an electrophoretic display element 40 instead of the organic EL element 20 of the display unit 1. Except for the foregoing point, the display unit 1B has a configuration similar to that of the display unit 1 according to the foregoing embodiment, and the operation and the effect thereof are similar to those of the display unit 1 according to the foregoing embodiment.

The display unit 1B has the transistor 10T and the holding capacitor 10C similar to those of the display unit 1. Above the transistor 10T and the holding capacitor 10C, the electrophoretic display element 40 is provided with the planarizing film 19 in between.

In the electrophoretic display element 40, for example, a display layer 43 configured of an electrophoretic display element may be sealed between a pixel electrode 41 and a common electrode 42. The pixel electrode 41 is arranged for each pixel, and may be, for example, electrically connected to the source-drain electrode 18 of the transistor 10T. The common electrode 42 is provided on an opposed substrate 44 as an electrode common to a plurality of pixels.

In the display unit 1B, as in the display unit 1 of the foregoing embodiment, resistance of the opposed region 12C of the oxide semiconductor film 12 is decreased by the hydrogen-containing film 16. Therefore, in this modification, voltage dependence of the holding capacitor 10C is allowed to be suppressed, and a desired capacity is allowed to be held stably.

### Application Examples

A description will be given of application examples in which any of the foregoing display units (the display units 1, 1A, and 1B) is applied to an electronic apparatus. Examples of the electronic apparatus may include a television, a digital camera, a notebook personal computer, a portable terminal device such as a mobile phone, and a video camcorder. In other words, any of the display units is applicable to an electronic apparatus in any field for displaying an image signal inputted from outside or an image signal generated inside as an image or a video.

(Module)

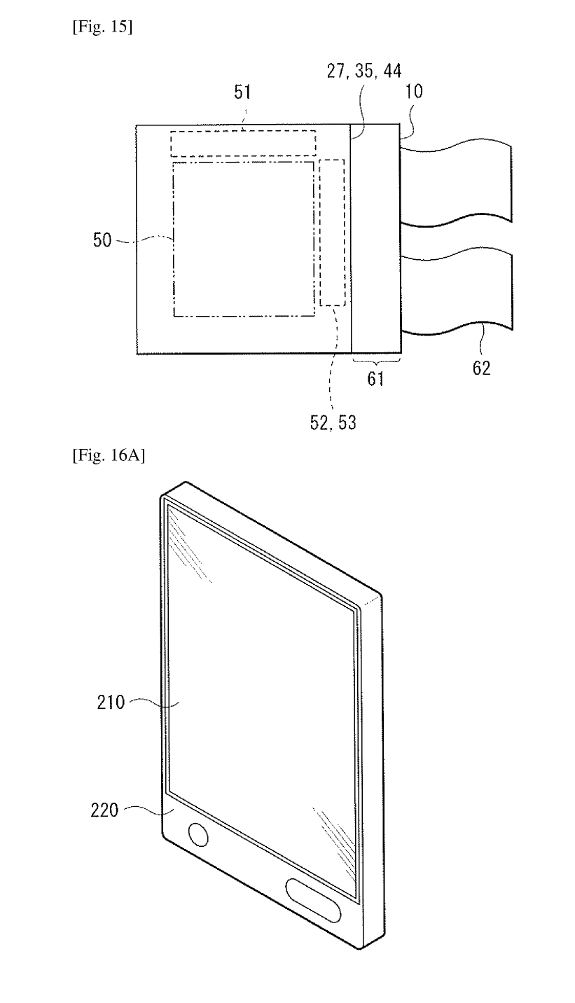

Any of the foregoing display units may be incorporated in various electronic apparatuses such as after-mentioned Application examples 1 to 7 as a module as illustrated in FIG. 15, for example. In the module, for example, a region 61 exposed from any of the sealing substrate 27 and the opposed substrates 35 and 44 is provided in one side of the substrate 11, and wirings of the horizontal selector 51, the write scanner 52, and the electric power source scanner 53 are extended to the exposed region 61 to form an external connection terminal (not illustrated). The external connection terminal may be provided with a Flexible Printed Circuit (FPC) 62 to input and output a signal.

### Application Example 1

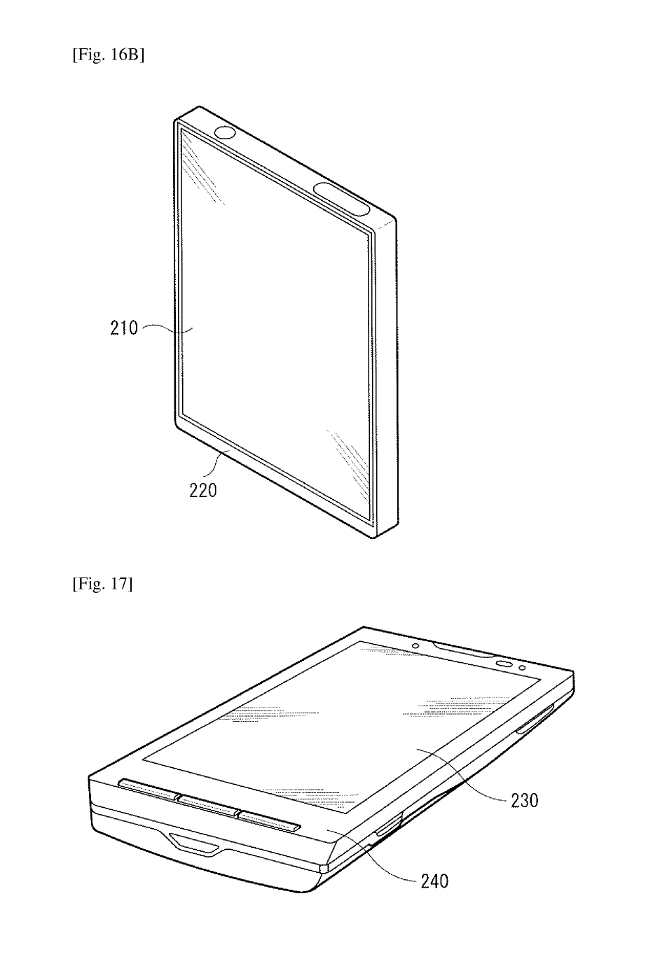

FIG. 16A and FIG. 16B respectively illustrate appearances of an electronic book to which the display unit according to any of the foregoing embodiments is applied. The electronic book may have, for example, a display section 210 and a non-display section 220, and the display section 210 is configured of the display unit according to any of the foregoing embodiments.

### Application Example 2

FIG. 17 illustrates an appearance of a smartphone to which the display unit according to any of the foregoing embodiments is applied. The smartphone may have, for example, a display section 230 and a non-display section 240. The display section 230 is configured of the display unit according to any of the foregoing embodiments.

### Application Example 3

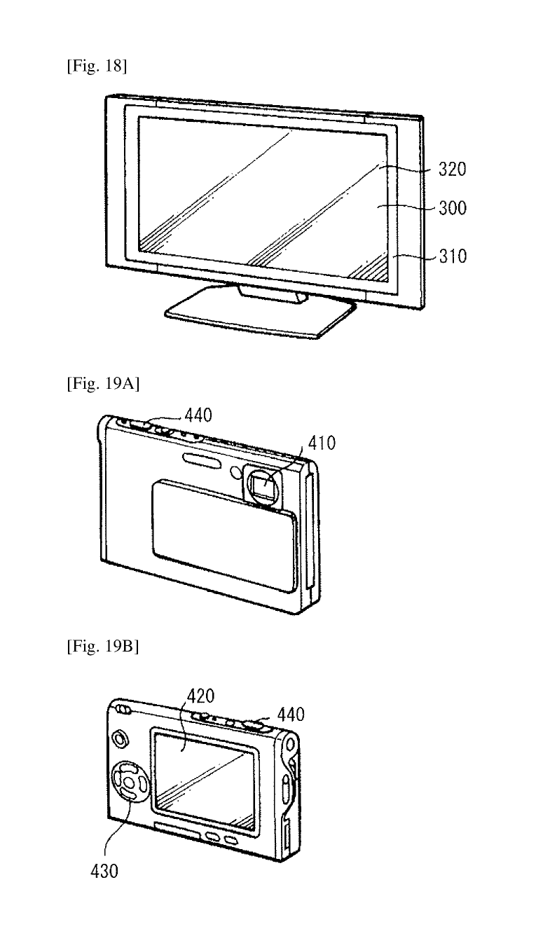

FIG. 18 illustrates an appearance of a television to which the display unit according to any of the foregoing embodiments is applied. The television may have, for example, an image display screen section 300 including a front panel 310 and a filter glass 320. The image display screen section 300 is configured of the display unit according to any of the foregoing embodiments.

### Application Example 4

FIG. 19A and FIG. 19B illustrate appearances of a digital camera to which the display unit according to any of the foregoing embodiments is applied. The digital camera may have, for example, a light emitting section 410 for a flash, a display section 420, a menu switch 430, and a shutter button 440. The display section 420 is configured of the display unit according to any of the foregoing embodiments.

### Application Example 5

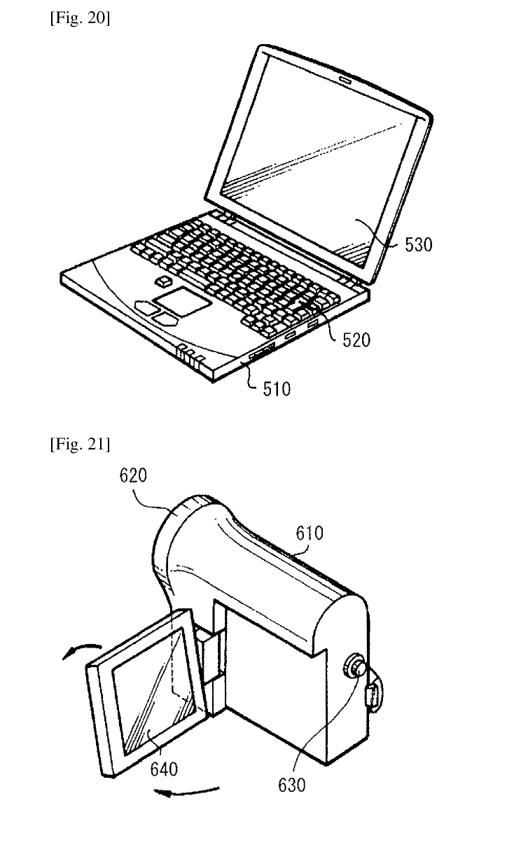

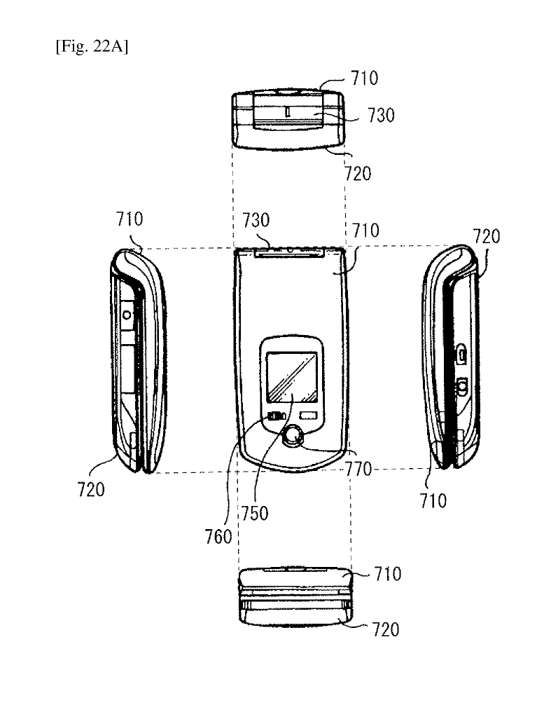

FIG. 20 illustrates an appearance of a notebook personal computer to which the display unit according to any of the foregoing embodiments is applied. The notebook personal computer may have, for example, a main body 510, a keyboard 520 for operation of inputting characters and the like, and a display section 530 for displaying an image. The display section 530 is configured of the display unit according to any of the foregoing embodiments.

### Application Example 6

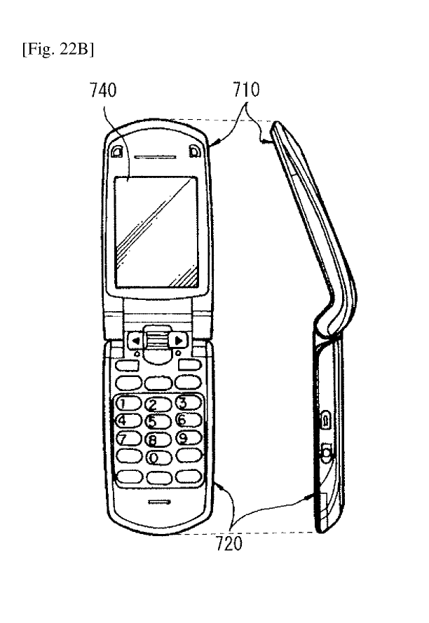

FIG. 21 illustrates an appearance of a video camcorder to which the display unit according to any of the foregoing embodiments is applied. The video camcorder may have, for example, a main body 610, a lens 620 for shooting a subject provided on the front side surface of the main body 610, a start-stop switch 630 for shooting, and a display section 640. The display section 640 is configured of the display unit according to any of the foregoing embodiments.

### Application Example 7

FIG. 22A and FIG. 22B illustrate appearances of a mobile phone to which the display unit according to any of the foregoing embodiments is applied. In the mobile phone, for example, an upper package 710 and a lower package 720 may be jointed by a joint section (hinge section) 730. The mobile phone may have a display 740, a sub-display 750, a picture light 760, and a camera 770. Either one or both of the display 740 and the sub-display 750 are configured of the display unit according to any of the foregoing embodiments.

While the present technology has been described with reference to the example embodiment and the modifications, the present technology is not limited to the foregoing embodiment and the like, and various modifications may be made. For example, in the foregoing embodiment and the like, the description has been given of the structure in which the high resistance film 15 is provided as an example. However, the high resistance film 15 may be removed after the low resistance region 12B is formed. However, the high resistance film 15 may be desirably provided as described above, since electric characteristics of the transistor 10T and the holding capacitor 10C are stably held thereby.

Further, in the foregoing embodiment and the like, the description has been given of the top-gate-type transistor 10T having the oxide semiconductor film 12, the gate insulating film 13T, and the gate electrode 14T in this order on the substrate 11. However, the present technology is also applicable to a bottom-gate-type transistor having the gate electrode 14T, the gate insulating film 13T, and the oxide semiconductor film 12 in this order on the substrate 11. However, in the case where the transistor 10T is a top-gate-type transistor, the display unit 1 is allowed to be manufactured more easily.

Further, in the foregoing embodiment and the like, the description has been given of the case in which the low resistance region 12B is provided in part of the thickness direction from the front surface (top surface) of the region other than the channel region 12C of the oxide semiconductor film 12. However, the low resistance region 12B may be provided in all of the thickness direction from the front surface (top surface) of the oxide semiconductor film 12.

In addition thereto, the material, the thickness, the film-forming method, the film-forming conditions, and the like of each layer are not limited to those described in the foregoing embodiment and the like, and other material, other thickness, other film-forming method, and other film-forming conditions may be adopted.

Furthermore, in the foregoing embodiment and the like, the description has been given of the configurations of the organic EL element 20, the liquid crystal display element 30, the electrophoretic display element 40, the transistor 10T, and the holding capacitor 10C with the specific examples. However, all the layers are not necessarily included, and other layer may be further included.

In addition thereto, the present technology is also applicable to other display unit using a display element such as an inorganic electroluminescence element, other than the organic EL element 20, the liquid crystal display element 30, and the electrophoretic display element 40.

Further, in the foregoing embodiment and the like, the description has been given of the configurations of the display unit with the specific examples. However, all the components are not necessarily included, and other component may be further included.

In addition thereto, in the foregoing embodiment and the like, the description has been given of the display unit as a specific example of a semiconductor device including the transistor 10T and the holding capacitor 10C. However, the present technology is applicable to an image detector or the like.

Furthermore, the technology encompasses any possible combination of some or all of the various embodiments described herein and incorporated herein.

It is possible to achieve at least the following configurations from the above-described example embodiments of the disclosure.

(1) A semiconductor device, including:
a transistor;
a capacitor; and
an oxide semiconductor film shared by the transistor and the capacitor,
wherein the capacitor includes a hydrogen-containing film that is in contact with the oxide semiconductor film.
(2) The semiconductor device according to (1), wherein the transistor includes: a gate electrode opposed to a channel region of the oxide semiconductor film with a gate insulating film in between; and
a pair of low resistance regions provided adjacent to the channel region of the oxide semiconductor film.
(3) The semiconductor device according to (2), wherein the transistor includes a source-drain electrode electrically connected to the low resistance regions of the oxide semiconductor film.
(4) The semiconductor device according to (3), wherein the capacitor includes a capacitor insulating film provided between the oxide semiconductor film and a capacitor electrode.
(5) The semiconductor device according to (4), wherein the transistor and the capacitor are provided on a substrate, the transistor includes the oxide semiconductor film, the gate insulating film, and the gate electrode in this order from the substrate, and the capacitor includes the hydrogen-containing film, the oxide semiconductor film, the capacitor insulating film, and the capacitor electrode in this order from the substrate.
(6) The semiconductor device according to (4) or (5), wherein the hydrogen-containing film extends around the capacitor electrode in planar view.
(7) The semiconductor device according to any one of (1) to (6), wherein the capacitor is arranged along a channel length direction of the transistor.
(8) The semiconductor device according to any one of (1) to (7), wherein the hydrogen-containing film includes silicon.
(9) The semiconductor device according to any one of (1) to (8), wherein the hydrogen-containing film includes one of a silicon nitride film, a silicon oxide film, a silicon oxynitride film, and an amorphous silicon film.
(10) The semiconductor device according to (2), further including a high resistance film that is in contact with the low resistance regions of the oxide semiconductor film.
(11) The semiconductor device according to (10), wherein the high resistance film includes a metal oxide.
(12) A semiconductor device, including a capacitor including a hydrogen-containing film that is in contact with an oxide semiconductor film.
(13) A display unit provided with a plurality of display elements and a semiconductor device configured to drive the plurality of display elements, the semiconductor device including:
a transistor;
a capacitor; and
an oxide semiconductor film shared by the transistor and the capacitor, wherein the capacitor includes a hydrogen-containing film that is in contact with the oxide semiconductor film.
(14) An electronic apparatus with a display unit, the display unit being provided with a plurality of display elements and a semiconductor device configured to drive the plurality of display elements, the semiconductor device including:
a transistor;
a capacitor; and
an oxide semiconductor film shared by the transistor and the capacitor, wherein the capacitor includes a hydrogen-containing film that is in contact with the oxide semiconductor film.

The present disclosure contains subject matter related to that disclosed in Japanese Priority Patent Application JP 2012-243319 filed in the Japan Patent Office on Nov. 5, 2012, the entire contents of which is hereby incorporated by reference.

It should be understood by those skilled in the art that various modifications, combinations, sub-combinations and alternations may occur depending on design re-quirements and other factors insofar as they are within the scope of the appended claims or the equivalents thereof.

### REFERENCE SIGNS LIST

1, 1A, 1B Display unit
10T Transistor
10C Holding capacitor
11 Substrate
12 Oxide semiconductor film
12T Channel region
12B Low resistance region
12C Electrode-opposed region
13T Gate insulating film
14T Gate electrode
15 High resistance film
15A Metal film
16 Hydrogen-containing film
17 Interlayer insulating film
18 Source-drain electrode
19 Planarizing film
20 Organic EL element
21 First electrode
22 Pixel separation film
23 Organic layer
24 Second electrode
25 Protective layer
26 Adhesion layer
27 Sealing substrate
H1, H2 Connection hole
50 Display region
51 Horizontal selector
52 Write scanner
53 Electric power scanner
DSL Scanning line
DTL Signal line
50A Pixel circuit
30 Liquid crystal display element
31, 41 Pixel electrode
32 Counter electrode
33 Liquid crystal layer
34A, 34B Alignment film
35, 44 Opposed substrate
36 Backlight
37A, 37B Polarizing plate
40 Electrophoretic display element
42 Common electrode
43 Display layer

1. A semiconductor device, comprising:
a transistor;
a capacitor; and
an oxide semiconductor film shared by the transistor and the capacitor, wherein the capacitor includes a hydrogen-containing film that is in contact with the oxide semiconductor film.

2. The semiconductor device according to claim 1, wherein the transistor includes:
a gate electrode opposed to a channel region of the oxide semiconductor film with a gate insulating film in between; and
a pair of low resistance regions provided adjacent to the channel region of the oxide semiconductor film.

3. The semiconductor device according to claim 2, wherein the transistor includes a source-drain electrode electrically connected to the low resistance regions of the oxide semiconductor film.

4. The semiconductor device according to claim 3, wherein the capacitor includes a capacitor insulating film provided between the oxide semiconductor film and a capacitor electrode.

5. The semiconductor device according to claim 4, wherein the transistor and the capacitor are provided on a substrate, the transistor includes the oxide semiconductor film, the gate insulating film, and the gate electrode in this order from the substrate, and the capacitor includes the hydrogen-containing film, the oxide semiconductor film, the capacitor insulating film, and the capacitor electrode in this order from the substrate.

6. The semiconductor device according to claim 4, wherein the hydrogen-containing film extends around the capacitor electrode in planar view.

7. The semiconductor device according to claim 1, wherein the capacitor is arranged along a channel length direction of the transistor.

8. The semiconductor device according to claim 1, wherein the hydrogen-containing film includes silicon.

9. The semiconductor device according to claim 1, wherein the hydrogen-containing film includes one of a silicon nitride film, a silicon oxide film, a silicon oxynitride film, and an amorphous silicon film.

10. The semiconductor device according to claim 2, further comprising a high resistance film that is in contact with the low resistance regions of the oxide semiconductor film.

11. The semiconductor device according to claim 10, wherein the high resistance film includes a metal oxide.

12. A semiconductor device, comprising a capacitor including a hydrogen-containing film that is in contact with an oxide semiconductor film.

13. A display unit provided with a plurality of display elements and a semiconductor device configured to drive the plurality of display elements, the semiconductor device comprising:
a transistor;
a capacitor; and
an oxide semiconductor film shared by the transistor and the capacitor, wherein the capacitor includes a hydrogen-containing film that is in contact with the oxide semiconductor film.

14. An electronic apparatus with a display unit, the display unit being provided with a plurality of display elements and a semiconductor device configured to drive the plurality of display elements, the semiconductor device comprising:
a transistor;
a capacitor; and
an oxide semiconductor film shared by the transistor and the capacitor, wherein the capacitor includes a hydrogen-containing film that is in contact with the oxide semiconductor film.
